(19) United States
(12) Patent Application Publication
(10) Pub. No.: US 2007/0226587 A1
(43) Pub. Date: Sep. 27, 2007

(54) Apparatus and method for receiving signal in communication system

(75) Inventors: Sung-Eun Park, Seoul (KR); Chi-Woo Lim, Suwon-si (KR); Thierry Lestable, Middlesex (GB); Dong-Seek Park, Yongin-si (KR); Jae-Yoel Kim, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/709,945

(22) Filed: Feb. 22, 2007

(30) Foreign Application Priority Data
Feb. 22, 2006 (KR) 17360/2006

(51) Int. Cl. H03M 13/00

(52) U.S. Cl. 714/758

(57) ABSTRACT

Provided are an apparatus and a method for receiving a signal in a communication system, which receives the signal, and decodes the received signal in a Low Density Parity Check (LDPC) decoding scheme in which the sequence of check node operations is scheduled, thereby improving the decoding performance of the LDPC code.

### PRIORITY

This application claims priority to an application filed in the Korean Industrial Property Office on Feb. 22, 2006 and assigned Ser. No. 2006-17360, the contents of which are incorporated herein by reference.

### BACKGROUND OF THE INVENTION

1. Field of the Invention

The present invention relates to an apparatus and a method for receiving a signal in a communication system, and in particular, to an apparatus and a method for receiving a signal in a communication system using a Low Density Parity Check (LDPC) code, which decodes the LDPC code using a horizontal shuffle scheduling algorithm whose sequence of check node operations is scheduled.

2. Description of the Related Art

Next-generation communication systems have evolved in the form of a packet service communication system for transmitting burst packet data to a plurality of Mobile Stations (MSs), and the packet service communication system has been designed suitable to be for mass data transmission. Further, next-generation communication systems are considering an LDPC code, together with a turbo code, as a channel code. The LDPC code is known to have an excellent performance gain at high-speed data transmission, and has an advantage in that it can enhance data transmission reliability by effectively correcting an error due to noise occurring in a transmission channel. Examples of next-generation communication systems considering the use of the LDPC code include the IEEE (Institute of Electrical and Electronics Engineers) 802.16e communication system, the IEEE 802.11n communication system, etc.

Reference will now be made to the structure of a signal transmission apparatus in a common communication system using a LDPC code, with reference to FIG. 1.

Referring to FIG. 1, the signal transmission apparatus includes an encoder 111, a modulator 113 and a transmitter 115. First, if an information vector s to be transmitted occurs in the signal transmission apparatus, the information vector s is delivered to the encoder 111. The encoder 111 generates a codeword vector c, that is, an LDPC codeword by encoding the information vector s in a predetermined encoding scheme, and then outputs the generated codeword vector c to the modulator 113. Here, the predetermined encoding scheme corresponds to an LDPC encoding scheme. The modulator 113 generates a modulation vector m by modulating the codeword vector c in a predetermined modulation scheme, and then outputs the generated modulation vector m to the transmitter 115. The transmitter 115 inputs therein the modulation vector m output from the modulator 113, executes transmission signal processing for the input modulation vector m, and then transmits the processed modulation vector m to a signal reception apparatus through an antenna.

Next, reference will be made to the structure of a signal reception apparatus in a common communication system using an LDPC code, with reference to FIG. 2.

Referring to FIG. 2, the signal reception apparatus includes a receiver 211, a demodulator 213 and a decoder 215. First, a signal transmitted by a signal transmission apparatus is received through an antenna of the signal reception apparatus, and the received signal is delivered to the receiver 211. The receiver 211 executes reception signal processing for the received signal to thereby generate a reception vector r, and then outputs the processed and generated reception vector r to the demodulator 213. The demodulator 213 inputs therein the reception vector r output from the receiver 211, generates a demodulation vector x by demodulating the input reception vector r in a demodulation scheme corresponding to a modulation scheme applied to a modulator of the signal transmission apparatus, that is, the modulator 113, and then outputs the generated demodulation vector x to the decoder 215. The decoder 215 inputs therein the demodulation vector x output from the demodulator 213, decodes the input demodulation vector x in a decoding scheme corresponding to an encoding scheme applied to an encoder of the signal transmission apparatus, that is, the encoder 111, and then outputs the decoded demodulation vector x into a finally restored information vector ŝ. Here, the decoding scheme, that is, an LDPC scheme, is a scheme using an iterative decoding algorithm based on a sum-product algorithm. The sum-product algorithm will be described in detail below.

An LDPC code is a code defined by a parity check matrix in which most elements have a value of 0, but a small minority of other elements have a non-zero value, for example, a value of 1. Further, the LDPC code can be expressed using a bipartite graph which is represented by variable nodes, check nodes and edges connecting the variable nodes and the check nodes with each other. Reference will now be made to FIG. 3 which illustrates a bipartite graph of an ordinary LDPC code by way of example.

The bipartite graph illustrated in FIG. 3 includes three check nodes, that is, check node C1, check node C2 and check node C3, six variable nodes, that is, variable node V1, variable node V2, variable node V3, variable node V4, variable node V5 and variable node V6, and edges connecting the three check node and the six variable nodes.

Next, a parity check matrix corresponding to the bipartite graph of an LDPC code, which is illustrated in FIG. 4 by way of example, will be described with reference to FIG. 4.

Referring to FIG. 4, each row of a parity check matrix shown in (a) corresponds to each check node of the bipartite graph in FIG. 3, and each column of the parity check matrix corresponds to each variable node of the bipartite graph in FIG. 3. Further, each element having a value of 1 in the parity check matrix indicates that a corresponding check node and a corresponding variable node are connected with each other by an edge, and each element having a value of 0 indicates that a corresponding check node and a corresponding variable node are not connected with each other on the bipartite graph.

If elements having a value of 0 are sequentially represented by “Iₙ” for the convenience of explanation, the parity check matrix shown in (a) can be expressed by a parity check matrix as shown in (b). That is, the parity check matrix shown in (b) includes twelve elements having a value of 1. That is, elements from I₁, to I₁₂ have a value of 1.

Further, the LDPC code can be decoded on the bipartite graph by using an iterative decoding algorithm based on a sum-product algorithm. Here, the sum-product algorithm is a type of message passing algorithm, and the message passing algorithm refers to an algorithm in which messages are exchanged on the bipartite graph through the edges, and an output message is calculated and updated from messages input into the variable nodes or the check nodes. Thus, since a decoder for decoding the LDPC code uses the iterative decoding algorithm based on the sum-product algorithm, it is less complex than a decoder for decoding a turbo code, and can be easily implemented as a parallel processing decoder.

How the message passing algorithm is implemented on the bipartite graph will now be described in detail.

An algorithm for implementing the message passing algorithm on the bipartite graph is largely classified into three algorithms, that is, a flooding algorithm, a horizontal shuffle scheduling algorithm and a vertical shuffle scheduling algorithm. Hereinafter, a description will be given for a procedure of updating a message in every iterative decoding when the respective three algorithms are used, with reference to FIGS. 3 and 4.

First, in using the flooding algorithm, check node operations for all the check nodes are simultaneously performed in every iterative decoding. That is, check node operations for the check node C1, the check node C2 and the check node C3 are simultaneously performed, so that edges connected with the respective check nodes, that is, (I₁, I₂, I₃, I₄), (I₅, I₆, I₇, I₈) and (I₉, I₁₀, I₁₁, I₁₂), are simultaneously and respectively message-updated. After the check node operations for all the check nodes are simultaneously performed in this way, variable node operations for all the variable operations are simultaneously performed. That is, variable node operations for the variable node V1, the variable node V2, the variable node V3, the variable node V4, the variable node V5 and the variable node V6 are simultaneously performed, so that edges connected with the respective variable nodes, that is, (I₁, I₅), (I₂, I₉), (I₃, I₆), (I₇, I₁₀), (I₄, I₁₁) and (I₈, I₁₂), are simultaneously and respectively message-updated.

Second, in using the horizontal shuffle scheduling algorithm, a check node operation for one check node is performed in every iterative decoding, and then variable node operations for all variable nodes connected with the check node, for which the check node operation has been performed, are simultaneously performed.

Specifically, if a check node operation for the check node C1 is performed first, edges connected with the check node C1, that is, (I₁, I₂, I₃, I₄), are message-updated. After the edges connected with the check node C1, that is, (I₁, I₂, I₃, I₄), are message-updated in this way, variable node operations for variable nodes connected with the check node C1, that is, the variable nodes V1, V2, V3 and V5, are simultaneously performed, so that edges connected with the respective variable nodes, that is, (I₁, I₅), (I₂, I₉), (I₃, I,₆) and (I₄, I₁₁), are simultaneously and respectively message-updated.

Next, if a check node operation for the check node C2 is performed, edges connected with the check node C2, that is, (I₅, I₆, I₇, I₈), are message-updated. After the edges connected with the check node C2, that is, (I₅, I₆, I₇, I₈), are message-updated in this way, variable node operations for variable nodes connected with the check node C2, that is, the variable nodes V1, V3, V4 and V6, are simultaneously performed, so that edges connected with the respective variable nodes, that is, (I₁, I₅), (I₃, I₆), (I₇, I₁₀) and (I₈, I₁₂), are simultaneously and respectively message-updated.

Finally, if a check node operation for the check node C3 is performed, edges connected with the check node C3, that is, (I₉, I₁₀, I₁₁, I₁₂), are message-updated. After the edges connected with the check node C3, that is, (I₉, I₁₀, I₁₁, 1₁₂), are message-updated in this way, variable node operations for variable nodes connected with the check node C3, that is, the variable nodes V2, V4, V5 and V6, are simultaneously performed, so that edges connected with the respective variable nodes, that is, (I₂, I₉), (I₇, I₁₀), (I₄, I₁₁,) and (I₈, I₁₂), are simultaneously and respectively message-updated.

Third, in the case of using the vertical shuffle scheduling algorithm, a variable node operation for one variable node is performed in every iterative decoding, and then message updates for all check nodes connected with the variable node, for which the variable node operation has been performed, are simultaneously performed.

Specifically, if a variable node operation for the variable node V1 is performed first, edges connected with the variable node V1, that is, (I₁, I₅), are message-updated. After the edges connected with the variable node V1, that is, (I₁, I₅), are message-updated in this way, check node operations for check nodes connected with the variable node V1, that is, the check nodes C1 and C2, are performed, so that edges connected with the respective check nodes, that is, (I₁, I₂, I₃, I₄) and (I₅, I₆, I₇, I₈), are message-updated, respectively.

Next, if a variable node operation for the variable node V2 is performed, edges connected with the variable node V2, that is, (I₂, I₉), are message-updated. After the edges connected with the variable node V2, that is, (I₂, I₉), are message-updated in this way, check node operations for check nodes connected with the variable node V2, that is, the check nodes C1 and C3, are performed, so that edges connected with the respective check nodes, that is, (I₁, I₂, I₃, I₄) and (I₉, I₁₀, I₁₁, I₁₂), are message-updated, respectively.

Next, if a variable node operation for the variable node V3 is performed, edges connected with the variable node V3, that is, (I₃, I₆), are message-updated. After the edges connected with the variable node V3, that is, (I₃, I₆), are message-updated in this way, check node operations for check nodes connected with the variable node V3, that is, the check nodes C1 and C2, are performed, so that edges connected with the respective check nodes, that is, (I₁, I₂, I₃, I₄) and (I₅, I₆, I₇, I₈), are message-updated, respectively.

Next, if a variable node operation for the variable node V4 is performed, edges connected with the variable node V4, that is, (I₇, I₁₀), are message-updated. After the edges connected with the variable node V4, that is, (I₇, I₁₀), are message-updated in this way, check node operations for check nodes connected with the variable node V4, that is, the check nodes C2 and C3, are performed, so that edges connected with the respective check nodes, that is, (I₅, I₆, I₇, I₈) and (I₉, i₁₀, I₁₁, i₁₂), are message-updated, respectively.

Next, if a variable node operation for the variable node V5 is performed, edges connected with the variable node V5, that is, (I₄, I₁₁), are message-updated. After the edges connected with the variable node V4, that is, (I₄, I₁₁,), are message-updated in this way, check node operations for check nodes connected with the variable node V5, that is, the check nodes C1 and C3, are performed, so that edges connected with the respective check nodes, that is, (I₁, I₂, I₃, I₄) and (I₉, I₁₀, I₁₁, I₁₂), are message-updated, respectively.

Finally, if a variable node operation for the variable node V6 is performed, edges connected with the variable node V6, that is, (I₈, I₁₂), are message-updated. After the edges connected with the variable node V6, that is, (I₈, I₁₂), are message-updated in this way, check node operations for check nodes connected with the variable node V6, that is, the check nodes C2 and C3, are performed, so that edges connected with the respective check nodes, that is, (I₅, I₆, I₇, I₈) and (I₉, I₁₀, I₁₁, I₁₂), are message-updated, respectively.

As described above, in the case of using the flooding algorithm, check node operations for all check nodes are simultaneously performed, and variable node operations for all variable nodes are also simultaneously performed. Unlike the flooding algorithm, in the horizontal shuffle scheduling algorithm, check node operations for respective check nodes are sequentially performed. Therefore, there is a strong need for a scheme for scheduling the sequence of check node operations when a message passing algorithm is implemented using the horizontal shuffle scheduling algorithm, thereby improving the decoding performance of an LDPC code.

### SUMMARY OF THE INVENTION

Accordingly, the present invention has been made to solve at least the above-mentioned problems occurring in the prior art, and one aspect of the present invention is to provide an apparatus and a method for receiving a signal in a communication system using an LDPC code.

Another aspect of the present invention is to provide an apparatus and a method for receiving a signal in a communication system using an LDPC code, which decodes the LDPC code by using a horizontal shuffle scheduling algorithm whose sequence of check node operations is scheduled.

In accordance with one aspect of the present invention, there is provided an apparatus for receiving a signal in a communication system. The apparatus includes a receiver for receiving the signal; and a decoder for decoding the received signal in a Low Density Parity Check (LDPC) decoding scheme in which a sequence of check node operations is scheduled.

In accordance with another aspect of the present invention, there is provided a method for receiving a signal in a communication system. The method includes receiving a signal; and decoding the received signal in a Low Density Parity Check (LDPC) decoding scheme in which a sequence of check node operations is scheduled.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram illustrating the structure of a signal transmission apparatus in a common communication system using an LDPC code;

FIG. 2 is a block diagram illustrating the structure of a signal reception apparatus in a common communication system using an LDPC code;

FIG. 3 is a bipartite graph of an ordinary LDPC code;

FIG. 4 is a parity check matrix corresponding to the bipartite graph of an LDPC code, illustrated in FIG. 3;

FIG. 5 is a view schematically illustrating the structure of MLD defined in accordance with the present invention; and

FIG. 6 is a block diagram illustrating the inner structure of a decoder in accordance with the present invention.

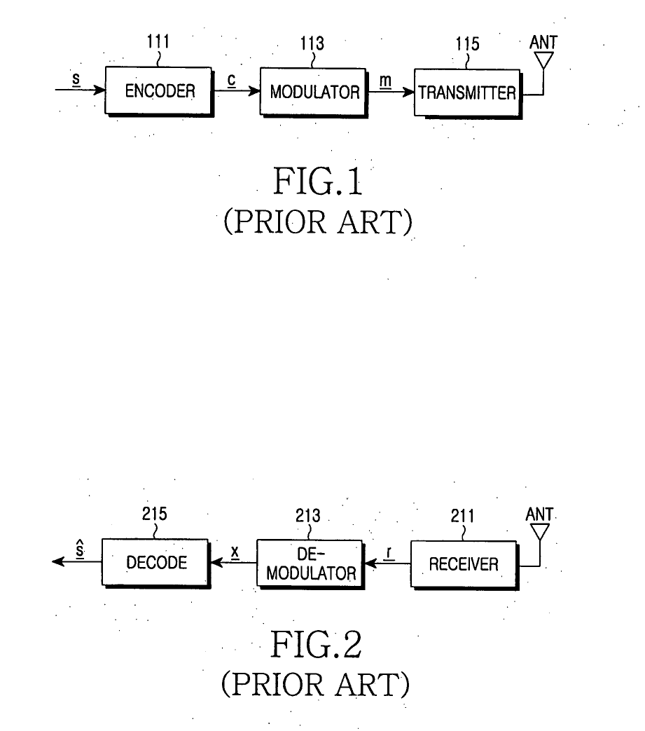

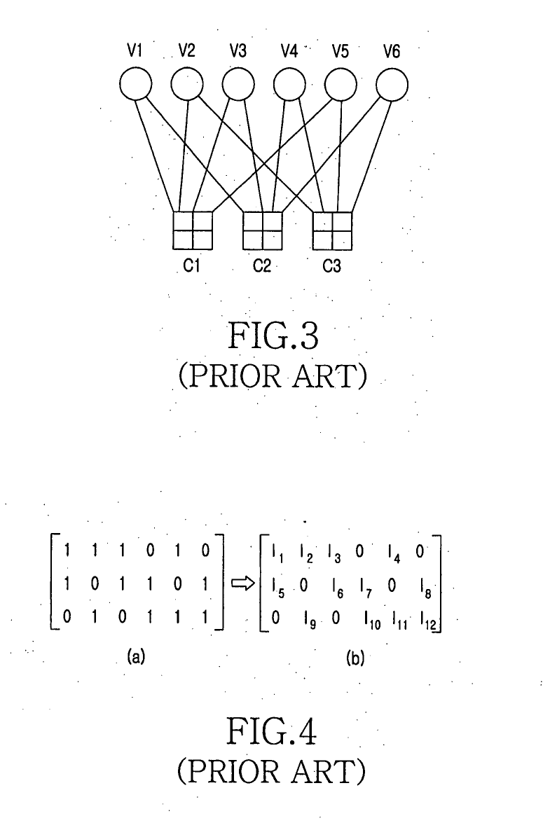

### DETAILED DESCRIPTION OF THE PREFERRED EMBODIMENT

Hereinafter, preferred embodiments of the present invention will be described with reference to the accompanying drawings. It should be noted that the similar components are designated by similar reference numerals although they are illustrated in different drawings. Also, in the following description, a detailed description of known functions and configurations incorporated herein will be omitted when it may obscure the subject matter of the present invention. Further, it should be noted that only parts essential for understanding the operations according to the present invention will be described and a description of parts other than the essential parts will be omitted in order not to obscure the gist of the present invention.

The present invention provides an apparatus and a method for receiving a signal in a communication system using an Low Density Parity Check (LDPC) code, which decodes the LDPC code while scheduling the sequence of check node operations when a message passing algorithm is implemented using a horizontal shuffle scheduling algorithm. Further, although separately described and illustrated herein, it is clear that when an LDPC code is decoded using the horizontal shuffle scheduling algorithm of the present invention, a procedure of scheduling the sequence of check node operations and decoding the LDPC code according thereto can be applied to a signal reception apparatus which has a structure as illustrated in FIG. 2.

As noted above, check node operations for respective check nodes are sequentially performed when the horizontal shuffle scheduling algorithm is used. Therefore, if the sequence of check nodes for which a check node operation is performed is scheduled, the decoding performance of an LDPC code may become different. Thus, the present invention provides a scheme for improving the decoding performance of an LDPC code by scheduling the sequence of check node operations when the horizontal shuffle scheduling algorithm is used.

First, in the present invention, an LDPC code is decoded using an iterative decoding algorithm based on a sum-product algorithm which is an algorithm for decoding the LDPC code. Here, the sum-product algorithm is a type of message passing algorithm, and the message passing algorithm refers to an algorithm in which messages are exchanged on a bipartite graph through edges, and an output message is calculated and updated from messages input into variable nodes or check nodes.

In the present invention, the message passing algorithm is implemented using a horizontal shuffle scheduling algorithm on the bipartite graph, and particularly the message passing algorithm is implemented on the bipartite graph by using a horizontal shuffle scheduling algorithm whose sequence of check node operations is scheduled. Reference will now be made to a procedure of scheduling the sequence of check node operations of the horizontal shuffle scheduling algorithm.

First, in order to schedule the sequence of check node operations, the present invention defines the following three parameters which are defined on a bipartite graph.

(1) Girth According to Check Node

In general, girth refers to a minimum cycle on a bipartite graph corresponding to a parity check matrix of an LDPC code. The bipartite graph includes various sized cycles, among which a cycle having a minimum size is the girth. Now, since the present invention provides a scheme for scheduling the sequence of check node operations when the horizontal shuffle scheduling algorithm is used, it is necessary to consider the girth for every check node, and thus a minimum cycle according to each check node is defined as “girth according to check node”.

(2) Number of Girth

As mentioned above, girth according to check node is defined by a minimum cycle according to each check node. However, girth according to check node may exist in plural numbers, which is defined as “number of girth”. That is, a plural number of minimum cycles may exist according to each check node, and thus the number of minimum cycles according to a check node is defined as number of girth.

(3) Multi-Layer Degree (MLD)

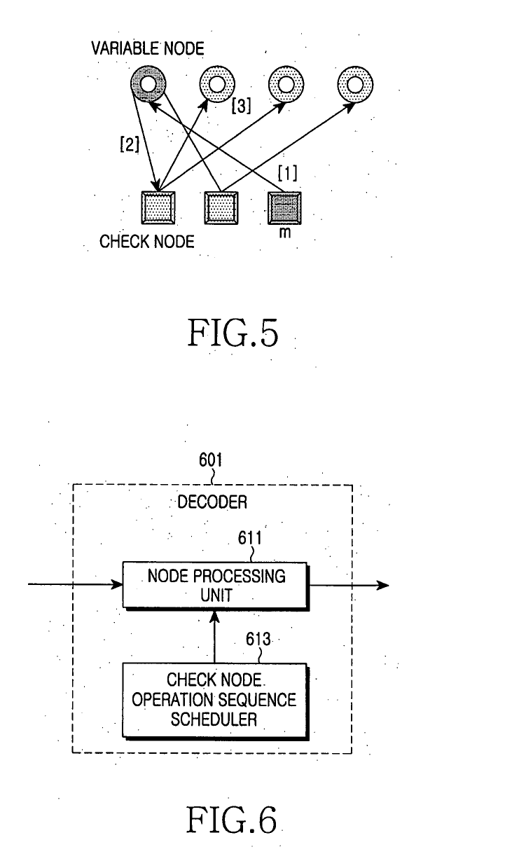

FIG. 5 illustrates the structure of MLD defined according to the present invention. Referring to FIG. 5, MLD is defined according to each layer of a check node.

Since the degree of the check node m is “1”, MLD in a first layer of the check node m is “1”, which can be expressed by Equation (1):
MLDₘ[1]=1 (1)

Further, in a second layer, the degree of a variable node connected with the check node m is “3”, one of which is the check node m. MLD in the second layer of the check node m can be expressed by Equation (2):
MLDₘ[2]=MLDₘ[1]+(3−1)=3 (2)

Further, MLD in a third layer of the check node m can be expressed by Equation (3):
MLDₘ[3]=MLDₘ[2]+(3−1)+(2−1)=6 (3)

MLDs in the respective layers of the check node m, as described above, can be summarized as Equation (4):

$${MLD}_{m} [ 1 ] = degree ( m ) \\ {MLD}_{m} [ k + 1 ] = {MLD}_{m} [ k ] + {\sum }_{x ∈ {N}^{k}} ( degree ( x ) - 1 ) , \\ k = 1 , 2 , … \qquad ( 4 )$$

In Equation (4), degree(x) denotes the degree of a check node or variable node x, and N^{(k)} denotes a set of all nodes belonging to a kth layer. In this embodiment of the present invention, layer depth must be predetermined for layers considered in using MLD. Here, the layer depth is a parameter indicating what number of layers in a check or variable node is a corresponding layer. As an example, if the layer depth is “1”, then it indicates that a corresponding layer is a first layer.

The above-defined three parameters, girth according to check node, number of girth and MLD, are arranged in increasing order and in decreasing order, respectively. Thus, by combining the priorities, increasing orders and decreasing orders of the respective three parameters with each other, various scenarios as shown below in Table 1 can be considered.

TABLE 1

| | |
|---|---|
| dG | iG |
| dG_iNG | iG_dNG |
| dG_iNG_dM | iG_dNG_iM |
| dG_iNG_iM | iG_dNG_dM |
| dG_dM | iG_iM |
| dG_dM_iNG | iG_iM_dNG |
| dG_iM | iG_dM |
| dG_iM_iNG | iG_dM_dNG |
| dM | iM |
| dM_iG | iM_dG |
| dM_iG_dNG | iM_dG_iNG |

In Table 1, “i” denotes increasing order, “d” denotes decreasing order, “G” denotes girth, “NG” denoted number of girth, and “M” denotes MLD. Further, a symbol “_” connecting parameters indicates that when preceding parameter conditions are identical, the next parameter condition is to be applied. For example, “dG_iNG” in Table 1 represents that check nodes are primarily arranged in decreasing order of girth, and check nodes having the same girth are secondly arranged in increasing order of number of girth.

Therefore, simulations are performed for any parity check matrix by applying the various scenarios as defined in Table 1, and the sequence of check node operations is scheduled using a selected scenario that shows the best decoding performance as a result of the simulations. Thereby, when an LDPC code is decoded using a horizontal shuffle scheduling algorithm whose sequence of check node operations is scheduled, the decoding performance of the LDPC code is improved, which can also be easily confirmed through simulations.

Here, when an LDPC code is decoded using a horizontal shuffle scheduling algorithm in which check node operations are performed while being scheduled in sequence, it can be noted that the decoding performance of the LDPC code is improved as compared with that when the LDPC code is decoded using the horizontal shuffle scheduling algorithm as described above in the prior art section, in which check node operations are sequentially performed according to the sequence of check nodes of a parity check matrix. Also, it is clear that the decoding performance of the LDPC code may be different depending on the types, characteristics and generation schemes of the parity check matrix.

Thus, if a parity check matrix to be used in a communication system is determined and a message passing algorithm is determined to be implemented using the horizontal shuffle scheduling algorithm, simulations are performed by applying the respective scenarios as defined in Table 1 to the determined parity check matrix. From a result of the simulations, a scenario showing the best decoding performance of an LDPC code is selected, and the sequence of check node operations in the horizontal shuffle scheduling algorithm is scheduled.

FIG. 6 illustrates the inner structure of a decoder 601 according to the present invention.

In FIG. 6, decoder 601 includes a node processing unit 611 and a check node operation sequence scheduler 613. The node processing unit 611 includes a check node processor (not illustrated) for performing check node operations and a variable node processor (not illustrated) for performing variable node operations. A procedure of performing check node operations by the check node processor and a procedure of performing variable node operations by the variable node processor are the same as a general check node operation procedure and a general variable node procedure, respectively, so a detailed description thereof will be omitted.

The check node operation sequence scheduler 613 schedules the sequence of check node operations which are performed by the check node processor include in the node processing unit 611. Here, the check node operation sequence scheduler 613 performs a procedure of scheduling the sequence of check node operations in the same manner as described above, so a detailed description thereof will also be omitted.

According to the present invention as describe above, when a message passing algorithm is implemented using horizontal shuffle scheduling algorithm in a communication system, the decoding performance of an LDPC code can be improved by scheduling the sequence of check node operations.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for receiving a signal in a signal reception apparatus of a communication system, the method comprising:
receiving a signal; and
decoding the received signal in a Low Density Parity Check (LDPC) decoding scheme in which a sequence of check node operations is scheduled.

2. The method as claimed in claim 1, wherein the LDPC decoding scheme in which the sequence of the check node operations is scheduled includes a LDPC decoding scheme in which the sequence of the check node operations is scheduled corresponding to any one scenario among a plurality of scenarios that are generated considering at least one of girth according to check node, number of girth and MLD.

3. The method as claimed in claim 2, wherein the girth according to check node represents a minimum cycle according to each check node on a bipartite graph corresponding to a parity check matrix of an LDPC code.

4. The method as claimed in claim 3, wherein the number of girth represents the number of the girths according to check node.

5. The method as claimed in claim 4, wherein the MLD of each layer in any check node m is expressed by a following equation,
$${MLD}_{m} [ 1 ] = degree ( m )$$
$${MLD}_{m} [ k + 1 ] = {MLD}_{m} [ k ] + {\sum }_{x ∈ {N}^{k}} ( degree ( x ) - 1 ) , \\ k = 1 , 2 , …$$
where, degree(x) denotes a degree of a check node or variable node x, and N^{(k)} denotes a set of all nodes belonging to a kth layer.

6. The method as claimed in claim 5, wherein the plurality of scenarios are generated considering at least one of the girth according to check node, the number of girth and the MLD which are arranged in increasing order and in decreasing order, respectively.

7. The method as claimed in claim 6, wherein the plurality of scenarios are represented as

| | |
|---|---|
| dG | iG |
| dG_iNG | iG_dNG |
| dG_iNG_dM | iG_dNG_iM |
| dG_iNG_iM | iG_dNG_dM |
| dG_dM | iG_iM |
| dG_dM_iNG | iG_iM_dNG |
| dG_iM | iG_dM |
| dG_iM_iNG | iG_dM_dNG |
| dM | iM |
| dM_iG | iM_dG |
| dM_iG_dNG | iM_dG_iNG |

where, “i” denotes increasing order, “d” denotes decreasing order, “G” denotes the girth, “NG” denoted the number of girth, “M” denotes the MLD, and a symbol “_” connecting parameters indicates that when preceding parameter conditions are identical, a next parameter condition is to be applied.

8. The method as claimed in claim 2, wherein the any one scenario is a scenario which has most superior decoding performance among the plurality of scenarios when the LDPC code is decoded by applying the scenarios to the parity check matrix of the LDPC code.

9. An apparatus for receiving a signal in a communication system, the apparatus comprising:
a receiver for receiving the signal; and
a decoder for decoding the received signal in a Low Density Parity Check (LDPC) decoding scheme in which a sequence of check node operations is scheduled.

10. The apparatus as claimed in claim 9, wherein the decoder comprises:
a check node operation sequence scheduler for controlling the sequence of the check node operations in such a manner as to be scheduled corresponding to the scheduled sequence of the check node operations; and
a node processing unit for scheduling the sequence of the check node operations according to control of the check node operation sequence scheduler, and decoding the received signal in the LDPC decoding scheme.

11. The apparatus as claimed in claim 10, wherein the sequence of the check node operations is scheduled corresponding to any one scenario among a plurality of scenarios that are generated considering at least one of girth according to check node, number of girth and MLD.

12. The apparatus as claimed in claim 11, wherein the girth according to check node represents a minimum cycle according to each check node on a bipartite graph corresponding to a parity check matrix of an LDPC code.

13. The apparatus as claimed in claim 12, wherein the number of girth represents the number of the girths according to check node.

14. The apparatus as claimed in claim 13, wherein the MLD of each layer in any check node m is expressed by a following equation,
$${MLD}_{m} [ 1 ] = degree ( m )$$
$${MLD}_{m} [ k + 1 ] = {MLD}_{m} [ k ] + {\sum }_{x ∈ {N}^{k}} ( degree ( x ) - 1 ) , \\ k = 1 , 2 , …$$
where, degree(x) denotes a degree of a check node or variable node x, and N^{(k)} denotes a set of all nodes belonging to a kth layer.

15. The apparatus as claimed in claim 14, wherein the plurality of scenarios are generated considering at least one of the girth according check node, the number of girth and the MLD which are arranged in increasing order and in decreasing order, respectively.

16. The apparatus as claimed in claim 15, wherein the plurality of scenarios are represented as

| | |
|---|---|
| dG | iG |
| dG_iNG | iG_dNG |
| dG_iNG_dM | iG_dNG_iM |
| dG_iNG_iM | iG_dNG_dM |
| dG_dM | iG_iM |
| dG_dM_iNG | iG_iM_dNG |
| dG_iM | iG_dM |
| dG_iM_iNG | iG_dM_dNG |
| dM | iM |
| dM_iG | iM_dG |
| dM_iG_dNG | iM_dG_iNG |

where, “i” denotes increasing order, “d” denotes decreasing order, “G” denotes the girth, “NG” denoted the number of girth, “M” denotes the MLD, and a symbol “_” connecting parameters indicates that when preceding parameter conditions are identical, a next parameter condition is to be applied.

17. The apparatus as claimed in claim 11, wherein the any one scenario is a scenario which has most superior decoding performance among the plurality of scenarios when the LDPC code is decoded by applying the scenarios to the parity check matrix of the LDPC code.
